(19) United States
(12) Patent Application Publication
(10) Pub. No.: US 2024/0405098 A1
(43) Pub. Date: Dec. 5, 2024

(54) GATE CONTACT STRUCTURE FOR A TRENCH POWER MOSFET WITH A SPLIT GATE CONFIGURATION

(71) Applicant: STMicroelectronics International N.V., Geneva (CH)

(72) Inventors: Maurizio Gabriele CASTORINA, Singapore (SG); Voon Cheng NGWAN, Singapore (SG)

(73) Assignee: STMicroelectronics International N.V., Geneva (CH)

(21) Appl. No.: 18/623,604

(22) Filed: Apr. 1, 2024

Related U.S. Application Data
(60) Provisional application No. 63/469,927, filed on May 31, 2023.

(51) Int. Cl. H01L 29/66; H01L 21/265; H01L 29/06; H01L 29/40; H01L 29/78

(52) U.S. Cl. CPC H01L 29/66734; H01L 21/26513; H01L 29/0696; H01L 29/401; H01L 29/407; H01L 29/7813

(57) ABSTRACT

An integrated circuit transistor device includes a semiconductor substrate providing a drain, a first doped region in the semiconductor substrate providing a source and a second doped region buried in the semiconductor substrate providing a body. A trench extends into the semiconductor substrate and passes through the first and second doped regions. An insulated polygate region within the trench surrounds a polyoxide region. The polygate region is formed by a first gate lobe and second gate lobe on opposite sides of the polyoxide region and a gate bridge over the polyoxide region. At a first region the gate bridge has a first thickness, and at a second region the gate bridge has a second thickness (greater than the first thickness). At the second region, a gate contact is provided at each trench to extend partially into the second thickness of the gate bridge.

### CROSS REFERENCE TO RELATED APPLICATIONS

This application claims priority from U.S. Provisional Application for Patent No. 63/469,927, filed May 31, 2023, the disclosure of which is incorporated herein by reference.

### TECHNICAL FIELD

Embodiments herein generally relate to metal oxide semiconductor field effect transistor (MOSFET) devices and, in particular, to a gate contact structure for a trench-type power MOSFET having a split gate configuration including a pair of polysilicon gate lobes laterally separated by a polyoxide region and electrically coupled by a polysilicon gate bridge.

### BACKGROUND

FIG. 1 shows a cross-section of a power metal oxide semiconductor field effect transistor (MOSFET) device 50. In this example, the MOSFET is an n-channel (nMOS) type device formed in and on a semiconductor substrate 52 doped with n-type dopant which provides the drain of the transistor 50. The substrate 52 has a front side 54 and a back side 56. A plurality of trenches 58 extend depthwise into the substrate 52 from the front side 54. The trenches 58 extend lengthwise (i.e., longitudinally) parallel to each other in a direction perpendicular to the cross-section (i.e., into and out the page of the illustration) and form strips (this type of transistor device commonly referred to in the art as a strip-FET type transistor).

A region 64 doped with a p-type dopant is buried in the substrate 52 at a depth offset from (i.e., below) the front side 54 and positioned extending parallel to the front side 54 on opposite sides of each trench 58. The doped region 64 forms the body (channel) region of the transistor, with the trench 58 passing completely through the doped body region 64 and into the substrate 52 below the doped body region 64. A region 66 doped with an n-type dopant is provided at the front side 54 of the substrate 52 and positioned extending parallel to the front side 54 on opposite sides of each trench 58 and in contact with the top of the doped body region 64. The doped region 66 forms the source of the transistor, with the trench 58 passing completely through the doped source region 66 and further extending, as noted above, completely through the doped body region 64 into the substrate 52 below the doped body region 64.

The side walls and bottom of each trench 58 are lined with a first (thick) insulating layer 60a. For example, the insulating layer 60a may comprise a thick oxide layer. The trench 58 is then filled by a first polysilicon material 62a, with the insulating layer 60a insulating the first polysilicon material 62a from the substrate 52. The polysilicon material 62a is a heavily n-type doped polysilicon material (for example, Phosphorus doped with a doping concentration of 5×10²⁰ at/cm³). During the process for fabricating the transistor 50, an upper portion of the insulating layer 60a (which would be adjacent to both the doped body region 64 and doped region 66) is removed from the trench 58 to expose a corresponding upper portion 61 of the polysilicon material 62a (see, FIG. 2A). This exposed upper portion 61 of the polysilicon material 62a is then converted (for example, using a thermal oxidation process) to form a polyoxide region 68 that is vertically aligned in the trench 58 with the remaining (lower) portion 63 of the polysilicon material 62a (See, FIG. 2B). This remaining lower portion 63 of the polysilicon material 62a forms a field plate electrode of the transistor 50 (referred to also as the polysource region because it is typically electrically shorted to the source region 66-this electrical connection is not explicitly shown in the figures). The side walls and bottom of the upper portion of each trench 58 are then lined with a second (thin) insulating layer 60b (see, FIG. 2C). For example, the insulating layer 60b may comprise a thermally grown thin oxide layer. The oxide lined upper portion of each trench 58 is then filled by a second polysilicon material 62b, with the insulating layer 60b insulating the second polysilicon material 62b from the substrate 52 (including regions 64 and 66). The second polysilicon material 62b forms the gate (referred to also as a polygate region) of the transistor 50 and includes a first (for example, left) gate lobe 621 and second (for example, right) gate lobe 622 which extend on opposite sides of the polyoxide region 68. The first and second gate lobes are electrically coupled by a gate bridge portion 623 extending over the polyoxide region 68. The insulating layer 60b forms the gate oxide layer.

A stack 70 of layers is formed above the upper surface of the substrate. The stack 70 includes an undoped oxide (for example, tetraethyl orthosilicate (TEOS)) layer 72 and a glass (for example, borophosphosilicate glass (BPSG)) layer 74. The stack 70 may further include additional insulating and/or barrier layers if needed. For example, a thin silicon nitride layer (not explicitly shown) may be provided between TEOS layer 72 and the upper surface 54 of the substrate 52.

With reference to the left side of FIG. 1, a source metal contact 80 extends through the layers of the stack 70, positioned between the locations of adjacent trenches 58, to make electrical contact with the doped source region 66. Each source metal contact 80 extends depthwise into the substrate to pass through the doped source region 66 and partially into the doped body region 64 (thus providing a body contact for the transistor 50 that is tied to the source). A source metal layer 82 extends over both the stack 70 and the source metal contacts 80 to provide an electrical connection to and between all source metal contacts 80. The layers of the stack 70 insulate both the source metal layer 82 and the source metal contacts 80 from the polygate (second polysilicon region 62b).

With reference now to the right side of FIG. 1, a gate metal contact 86 extends through the layers of the stack 70, positioned in alignment with the locations of the trenches 58, to make electrical contact with the second polysilicon region 62b in each trench 58 (for example, by making contact at the location of the bridge portion 623). It will be noted that the gate metal contact 86 preferably extends depthwise at least partially into the filled trench, for example extending into at least the upper part of the bridge portion 623 (and perhaps extending completely through the bridge portion). A gate metal layer 88 extends over both the stack 70 and the gate metal contacts 86 to provide an electrical connection to and between all gate metal contacts 86. The layers of the stack 70 insulate both the gate metal layer 88 and the gate metal contacts 86 from the source metal contacts and source regions. The polyoxide region 68 insulates the polysource region 62a from the gate metal contact 86.

The cross-sections on the left and right sides of FIG. 1 are in practice actually longitudinally offset from each other in the direction perpendicular to the cross-section (i.e., into and out the page of the illustration). In this configuration, an insulating separation is provided between the source metal layer 82 and the gate metal layer 88.

A drain metal layer 84 extends over the back side 56 of the substrate 52 to provide a metal connection to the drain.

The transistor 50 could instead be a pMOS type transistor where the substrate 52 and doped source region 56 are both p-type doped and the body region 54 is n-type doped.

FIG. 3A shows a scanning electron micrograph (SEM) cross-sectional image of a single cell of the transistor 50 corresponding to the left side of FIG. 1.

During the formation of the polyoxide region 68 (see, FIG. 2B), there is a lateral and vertical material expansion as the polysilicon material 62a is converted into the polyoxide region 68. This expansion induces a tension which can produce a void (or seam or cavity) within the polyoxide material. The existence and location of such voids in the polyoxide region 68 is unpredictable. FIG. 3B shows a scanning electron micrograph (SEM) cross-sectional image focusing on the region where the trench 58 is located to illustrate by example the existence of such a void (see, also, FIG. 2B). Depending on the width of the trench 58 and the size of the polygate formed by lobes 621, 622 and bridge 623, the void in the polyoxide region 68 may extend close to the inner surface of the polygate (see, FIG. 3C) and this can have an impact on the formation of the gate contact 86 and, as will be discussed below, increase the risk of current leakage and/or the formation of a short to the source through the polysource region 62a.

The process for formation of the gate contact 86 utilizes a mask with a mask opening aligned with the center of the trench 58. An etch performed using this mask produces a gate opening extending through the stack 70 and at least partially into, if not completely through, the bridge 623 of the second polysilicon region 62b which forms the polygate. That etch may include multiple, discrete, etch steps including a first etch to remove the layers of the stack 70 and a second etch to extend into the bridge 623 for a desired depth. The size of the mask opening, and the corresponding gate opening, is typically designed to be about, and more preferably less than, one-half the size (width) of the trench 58 and is generally speaking preferably aligned with the center of the trench. A barrier layer 92 formed of a Titanium-Titanium Nitride (Ti—TiN) material is then conformally deposited into the etched gate opening, and the gate opening is then filled with a plug 94 made of a conductive material (such as, for example, Tungsten) to form the gate contact 86. FIG. 3C shows a scanning electron micrograph (SEM) cross-sectional image focusing on the gate contact 86 and illustrating that the gate opening has passed completely through the gate bridge 623 to reach the polyoxide region 68.

Control over the depth of the second etch is difficult to ensure, and the possible existence and location of the void in the polyoxide region 68 is difficult to predict. There accordingly exists a non-negligible risk that the second etch will pass completely through the bridge 623, with the gate opening extending partially into the polyoxide region 68 to reach the void. Additionally, the etched opening may extend at least partially around the polyoxide region 68. The conformally deposited Ti—TiN barrier layer may not adequately cover this location due to the difficult topology presented by the possible void in combination with the gate opening, and thus the conductive material for the plug that is deposited in the gate opening may present a leakage path or short-circuit between the polygate and the polysource provided by the field plate (which, as noted above, is electrically connected to the source region).

United States Patent Publication No. 2022/0320332 (incorporated herein by reference) presents solutions to address the foregoing problem in power MOSFET devices and provide for a better electrical contact to a split gate configuration including a pair of polysilicon gate lobes laterally separated by a polyoxide region and electrically coupled by a polysilicon gate bridge.

Reference is now made to FIG. 4 which shows a lateral cross-section of a power metal oxide semiconductor field effect transistor (MOSFET) device 110 in accordance with the teaching of United States Patent Publication No. 2022/0320332. In this example, the MOSFET is an n-channel (nMOS) type device formed in and on a semiconductor substrate 112 doped with n-type dopant which provides the drain of the transistor 110. The substrate 112 has a front side 114 and a back side 116. A plurality of trenches 118 extend depthwise into the substrate 112 from the front side 114. The trenches 118 longitudinally extend with a desired length parallel to each other in a direction perpendicular to the cross-section (i.e., into and out of the page of the illustration) and form strips (this type of transistor device commonly referred to in the art as a strip-FET type transistor).

A region 124 doped with a p-type dopant is buried in the substrate 112 at a depth offset from (i.e., below) the front side 114 and positioned laterally extending parallel to the front side 114 on opposite sides of each trench 118. The doped region 124 forms the body (channel) region of the transistor, with the trench 118 passing completely through the doped body region 124 and into the substrate 112 below the doped body region 124. A surface implant region 126 doped with an n-type dopant is provided at the front side 114 of the substrate 112 and positioned extending parallel to the front side 114 on opposite sides of each trench 118 and in contact with the top of the doped body region 124. The doped region 126 forms the source of the transistor, with the trench 118 passing completely through the doped source region 126 and further extending, as noted above, completely through the doped body region 124 into the substrate 112 below the doped body region 124.

The side walls and bottom of each trench 118 are lined with a first insulating layer 120a. For example, the insulating layer 120a may comprise a thick oxide layer. The trench 118 is then filled by a first polysilicon material 122a, with the insulating layer 120a insulating the first polysilicon material 122a from the substrate 112. The first polysilicon material 122a is a heavily n-type doped polysilicon material (for example, Phosphorus doped with a doping concentration of 5×10²⁰ at/cm³). With additional reference to FIGS. 2A-2C, during the process for fabricating the transistor 110, an upper portion of the insulating layer 120a (which would be adjacent to both the doped body region 124 and doped region 126) is removed from the trench 118 to expose a corresponding upper portion of the first polysilicon material 122a. This exposed upper portion of the first polysilicon material 122a is then converted (for example, using a thermal oxidation process) to form a polyoxide region 128 that is vertically aligned in the trench 118 with the remaining (lower) portion of the first polysilicon material 122a. This remaining lower portion of the first polysilicon material 122a forms a field plate electrode of the transistor 110 (referred to also as the polysource region because it is typically electrically shorted to the source region 126—this electrical connection is not explicitly shown in the figures). The side walls and bottom of the upper portion of each trench 118 are then lined with a second insulating layer 120b. For example, the insulating layer 120b may comprise a thermally grown oxide layer. The upper portion of each trench 118 is then filled by a second polysilicon material 122b, with the insulating layer 120b insulating the second polysilicon material 122b from the substrate 112 (including regions 124 and 126). The second polysilicon material 122b forms the gate (referred to as a polygate region) of the transistor 110 and includes a first (for example, left) gate lobe 621 and second (for example, right) gate lobe 622 which longitudinally extend in the trench on opposite sides of the polyoxide region 128. The first and second gate lobes are connected by a gate bridge portion 623 laterally extending over the polyoxide region 128. The insulating layer 120b forms the gate oxide layer.

A stack 130 of layers is formed above the upper surface of the substrate. The stack 130 includes an undoped oxide (for example, tetraethyl orthosilicate (TEOS)) layer 132 and a glass (for example, borophosphosilicate glass (BPSG)) layer 134. The stack 130 may further include additional insulating and/or barrier layers if needed. For example, a thin silicon nitride layer (not explicitly shown) may be provided between TEOS layer 132 and the upper surface 114 of the substrate 112.

With reference to the left side of FIG. 4, a source metal contact 140 extends through the layers of the stack 130, positioned between the locations of adjacent trenches 118, to make electrical contact with the doped source region 126. Each source metal contact 140 extends depthwise into the substrate to pass through the doped source region 136 and partially into the doped body region 134 (thus providing a body contact for the transistor 110 that is tied to the source). A source metal layer 142 extends over both the stack 130 and the source metal contacts 140 to provide an electrical connection to and between all source metal contacts 140. The layers of the stack 130 insulate both the source metal layer 142 and the source metal contacts 140 from the polygate (second polysilicon region 122b).

With reference now to the right side of FIG. 4, the gate metal contact for each polygate is formed by a pair of contacts 861 and 862, where each contact 861, 862 extends through the layers of the stack 130, positioned in vertical alignment with the location of a corresponding lobe 621, 622 (respectively) of the polygate, to make electrical contact with the respective lobe of the second polysilicon region 122b in each trench 118. In a preferred implementation, each gate metal contact 861, 862 extends depthwise at least partially into an upper portion of the corresponding lobe 621, 622 on either side of the bridge 623. A gate metal layer 148 extends over both the stack 130 and the gate metal contacts 861, 862 to provide an electrical connection to and between all gate metal contacts 861, 862. The layers of the stack 130 insulate both the gate metal layer 148 and the gate metal contacts 861, 862 from the source metal contacts and source regions. It will be noted that a portion of the stack serves to laterally insulate the contact 861 from the contact 862 at the level of layers within the stack.

The cross-sections on the left and right sides of FIG. 4 are, in practice, actually longitudinally offset from each other in the direction perpendicular to the cross-section (i.e., into and out of the page of the illustration). In this configuration, an insulating separation is provided between the source metal layer 142 and the gate metal layer 148.

A drain metal layer 144 extends over the back side 116 of the substrate 112 to provide a metal connection to the drain.

The transistor 110 could instead be a pMOS type transistor where the substrate 112 and doped source region 126 are both p-type doped and the body region 124 is n-type doped.

FIGS. 5A and 5B are plan views (i.e., looking downward towards the front surface of the substrate) comparing layouts for the transistors 50 and 110 with a specific focus showing the relative locations of the contacts 86 and the pair of contacts 861 and 862. The dotted line indicates the center line of each longitudinally extending trench, and the dash-dot line indicates the general location of the longitudinal center of each lobe of the polygate. FIG. 5A generally corresponds to the implementation shown on the right side of FIG. 1, while FIG. 5B generally corresponds to the implementation shown on the right side of FIG. 4. Although only one pair of contacts 861 and 862 per trench is shown in FIG. 5B, it will be understood that this is by example only and that more than one pair per trench may be used if desired.

The structure of the gate contact shown in FIG. 4 which utilizes a pair of side-by-side arranged contacts 861 and 862 addresses the concerns with problems that may arise in connection with the polyoxide region 148 possibly including a void. The combined size of the pair of contacts 861 and 862 is, preferably, substantially equal to the size of the gate contact 86 shown in FIG. 1, and thus will provide substantially identical performance in terms of gate resistance. Splitting of each gate contact into two parts (contacts 861 and 862) and vertically aligning each part with a corresponding lobe 621, 622 of the polygate avoids making contact with the polygate in the center portion of the trench (i.e., at the location of the gate bridge region) and thus minimizes the risk that the etch used to form the contact openings will reach the void location.

In this FIG. 4 embodiment, each contact 861, 862 may have a length dimension (in the longitudinal direction) of between 0.1 μm and 10μm and a width dimension (perpendicular to the length dimension in the lateral direction) of between 0.1μm and 1 μm.

It will be noted that in the implementation shown in FIG. 4, with a lateral side-by-side arrangement of the pair of contacts 861, 862 the cross-section at a given location longitudinally along the length of the trench passes through both of the contacts 861, 862. The fabrication of a device having such an implementation requires that the gate mask include a very thin resist portion aligned with the spacing between the adjacent contacts at that given location. It is possible that this very thin resist portion could lift off during fabrication processing and adversely affect the accuracy of the etching operation to form each pair of gate contact openings. For example, malformed openings for each of the gate contacts could occur, or a merger of the two separate openings for the side-by-side pair of contacts into one large opening could occur. A solution to this concern is to instead design the gate mask so that the individual mask openings for producing the contacts 861, 862 are longitudinally offset from each other in the direction perpendicular to the cross-section (i.e., into and out of the page of the illustration).

A transistor 110′ structure resulting from such an arrangement of the mask openings is shown in FIG. 6. Like references in FIG. 6 refer to like or similar parts as shown in FIG. 4. The left side of FIG. 6 corresponds to the left side of FIG. 4. The middle and right portions of FIG. 6 illustrate the longitudinal offsetting of the gate contacts 861 and 862 for a given trench which result from a corresponding longitudinal offsetting of the mask openings. In particular, the middle portion of FIG. 6 shows the cross section at locations where the mask openings for forming the first gate contacts 861 have been utilized so as to make electrical contact to the corresponding first (left) lobe 621 of the polygate. The right portion of FIG. 6 shows the cross section at locations where the mask openings for forming the second gate contacts 862 have been utilized so as to make electrical contact to the corresponding second (right) lobe 622 of the polygate. Notwithstanding the longitudinal offset of the individual gate openings, it will be noted that each gate contact to a polygate within the trench is still formed by a pair of contacts 861 and 862.

In this FIG. 6 embodiment, each contact 861, 862 may have a length dimension (in the longitudinal direction) of between 0.1 μm and 10 μm and a width dimension (perpendicular to the length dimension in the lateral direction) of between 0.1 μm and 1 μm. It will be noted that with the longitudinal offsetting of the contacts 861, 862 in FIG. 6, each individual contact may be fabricated to have a wider width than the corresponding contact for the FIG. 4 embodiment where the side-by-side arrangement may impose a constraint on contact width.

FIG. 7A shows a scanning electron micrograph (SEM) cross-sectional image of a single cell of the transistor 110′ corresponding to the middle portion of FIG. 6 and focusing on the gate contact 861 for lobe 621 of the polygate.

FIG. 7B shows a scanning electron micrograph (SEM) cross-sectional image of a single cell of the transistor 110′ corresponding to the right side of FIG. 6 and focusing on the gate contact 862 for lobe 622 of the polygate.

FIGS. 8A and 8B are plan views (i.e., looking downward towards the front surface of the substrate) comparing layouts for the transistors 110 and 110′ with a specific focus showing the relative locations of the pair of contacts 861 and 862. The dotted line indicates the center line of each longitudinally extending trench, and the dash-dot line indicates the general location of the center of each lobe of the polygate. It will be noted that a longitudinal center of each contact 861, 862 is positioned between the longitudinal center of the corresponding gate lobe and the longitudinal center of the trench. This ensures that placement of the contact does not risk bridging across the gate oxide and shorting the polygate to the doped source region. FIG. 8A generally corresponds to the implementation shown on the right side of FIG. 4 (see, also FIG. 5B), while FIG. 8B generally corresponds to the implementation shown on the middle portion and right side of FIG. 6. Although only one pair of contacts 861 and 862 per trench is shown in FIGS. 8A and 8B, it will be understood that this is by example only and that more than one pair per trench may be used if desired. From FIG. 8B, it will be noted that the longitudinal offset of the pair of contacts 861 and 862 of a given trench is such that no cross section through that given trench in a plane perpendicular to the longitudinal direction of the given trench will pass through both the first gate contact and the second gate contact. This is effectuated by setting a sufficient longitudinal offset distance D between the end of the first gate contact and the adjacent end of the second gate contact in the longitudinal direction of the trench.

A concern with the solutions of FIGS. 4 and 6 is that it is difficult to implement in connection with transistors having a reduced pitch or transistors designed for lower voltage classes. The reason for this is that the reduced pitch, with a smaller trench opening, presents a smaller area at the gate lobe and it becomes increasingly difficult with scaling of the device to fit the off-centered contact 861, 862 into the gate lobe 621, 622, respectively.

There is accordingly a need in the art to provide for a further improved gate contact and method of making same for use in connection with a trench-type power MOSFET having a split gate configuration including a pair of polysilicon gate lobes laterally separated by a polyoxide region and electrically coupled by a polysilicon gate bridge.

### SUMMARY

In an embodiment, a method comprises: forming a trench in a semiconductor substrate; lining sidewalls and a bottom of the trench with a first insulating layer; filling the trench with a first polysilicon material; forming a mask covering the trench at a first region of the semiconductor substrate, said mask including a first opening over the trench at a second region of the semiconductor substrate; using said first opening, etching to selectively remove a first portion of the first polysilicon material at said second region of the semiconductor substrate; removing the mask; etching to selectively remove a second portion of the first polysilicon material at said first region of the semiconductor substrate and remove a third portion of the first polysilicon material at said second region of the semiconductor substrate; etching to selectively remove an upper portion of the first insulating layer in said trench to a first depth at said first region of the semiconductor substrate and to second depth at said second region of the semiconductor substrate, said second depth being greater than said first depth, to expose an upper portion of the first polysilicon material in an upper portion of said trench; converting the exposed upper portion of the first polysilicon material in said trench to a polyoxide material; lining sidewalls and a bottom of the upper portion of said trench with a second insulating layer; and filling the upper portion of said trench with a second polysilicon material.

In an embodiment, a method comprises: forming a trench in a semiconductor substrate; lining sidewalls and a bottom of the trench with a first insulating layer; filling the trench with a first polysilicon material; selectively recessing the first polysilicon material in the trench at a first region of the semiconductor substrate to a first level; selectively recessing the first polysilicon material in the trench at a second region of the semiconductor substrate to a second level, said second level being greater in depth than said first level; selectively recessing an upper portion of the first insulating layer in said trench to a first depth in the first region and to a second depth in the second region in order to expose an upper portion of the recessed first polysilicon material in an upper portion of said trench; converting the exposed upper portion of the first polysilicon material in said trench to a polyoxide material; lining sidewalls and a bottom of the upper portion of said trench with a second insulating layer; and filling the upper portion of said trench with a second polysilicon material.

In an embodiment, an integrated circuit transistor device comprises: a semiconductor substrate providing a drain; a first doped region in the semiconductor substrate providing a source; a second doped region buried in the semiconductor substrate below the first doped region and providing a body; a trench extending into the semiconductor substrate and passing through the first and second doped regions; a polyoxide region within the trench; and a polygate region within the trench, said polygate region comprising: a first gate lobe on a first side of the polyoxide region, a second gate lobe on a second side of the polyoxide region opposite said first side, and a gate bridge extending over the polyoxide region; wherein, at a first region of the semiconductor substrate, the polyoxide region is recessed within the trench to a first level and the first and second gate lobes extend to a first depth within the trench; wherein, at a second region of the semiconductor substrate, the polyoxide region is recessed within the trench to a second level and the first and second gate lobes extend to a second depth within the trench; and wherein said second level is greater in depth than said first level the first and said second depth is greater than said first depth.

In an embodiment, an integrated circuit transistor device comprises: a semiconductor substrate providing a drain; a first doped region in the semiconductor substrate providing a source; a second doped region buried in the semiconductor substrate below the first doped region and providing a body; a trench extending into the semiconductor substrate and passing through the first and second doped regions; a polyoxide region within the trench; a polygate region within the trench, said polygate region comprising: a first gate lobe on a first side of the polyoxide region, a second gate lobe on a second side of the polyoxide region opposite said first side, and a gate bridge extending over the polyoxide region; wherein, at a first region of the semiconductor substrate, the gate bridge has a first thickness; wherein, at a second region of the semiconductor substrate, the gate bridge has a second thickness that is greater than the first thickness; a stack of insulating layers covering the transistor gate electrode, the trench and the semiconductor substrate; an opening at said second region of the semiconductor substrate aligned with the trench and extending through the stack of insulating layer and partially extending into the second thickness of the gate bridge; and a gate contact in said opening.

### BRIEF DESCRIPTION OF THE DRAWINGS

For a better understanding of the embodiments, reference will now be made by way of example only to the accompanying figures in which:

FIG. 1 is a cross-section of a power metal oxide semiconductor field effect transistor (MOSFET) device;

FIGS. 2A-2C show process steps in the manufacture of the power MOSFET device of FIG. 1;

FIGS. 3A-3C are scanning electron micrograph images of a cross-section of the power MOSFET device of FIG. 1;

FIG. 4 is a cross-section of a power MOSFET device;

FIGS. 5A and 5B illustrate gate contact layout configurations for the power MOSFET devices of FIGS. 1 and 4, respectively;

FIG. 6 is a cross-section of a power MOSFET device;

FIGS. 7A-7B are scanning electron micrograph images of a cross-section of the power MOSFET device of FIG. 6;

FIGS. 8A and 8B illustrate gate contact layout configurations for the power MOSFET devices of FIGS. 4 and 6, respectively;

FIG. 9 is a cross-section of a power MOSFET device;

FIGS. 10A-1 to 10G-2 show process steps in the manufacture of the power MOSFET device of FIG. 9; and

FIG. 11 illustrates gate and source contact layout for the power MOSFET device of FIG. 9.

### DETAILED DESCRIPTION

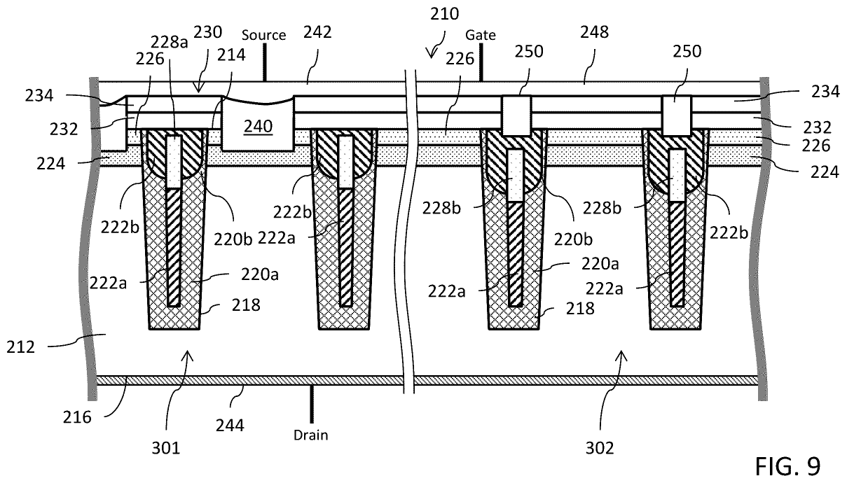

Reference is now made to FIG. 9 which shows a lateral cross-section of a power metal oxide semiconductor field effect transistor (MOSFET) device 210. In this example, the MOSFET is an n-channel (nMOS) type device formed in and on a semiconductor substrate 212 doped with n-type dopant which provides the drain of the transistor 210. The substrate 212 has a front side 214 and a back side 216. A plurality of trenches 218 extend depthwise into the substrate 212 from the front side 214. The trenches 218 longitudinally extend with a desired length parallel to each other in a direction perpendicular to the cross-section (i.e., into and out of the page of the illustration) and form strips (this type of transistor device commonly referred to in the art as a strip-FET type transistor).

A region 224 doped with a p-type dopant is buried in the substrate 212 at a depth offset from (i.e., below) the front side 214 and positioned laterally extending parallel to the front side 214 on opposite sides of each trench 218. The doped region 224 forms the body (channel) region of the transistor, with the trench 218 passing completely through the doped body region 224 and into the substrate 212 below the doped body region 224. A surface implant region 226 doped with an n-type dopant is provided at the front side 214 of the substrate 212 and positioned extending parallel to the front side 214 on opposite sides of each trench 218 and in contact with the top of the doped body region 224. The doped region 226 forms the source of the transistor, with the trench 218 passing completely through the doped source region 226 and further extending, as noted above, completely through the doped body region 224 into the substrate 212 below the doped body region 224.

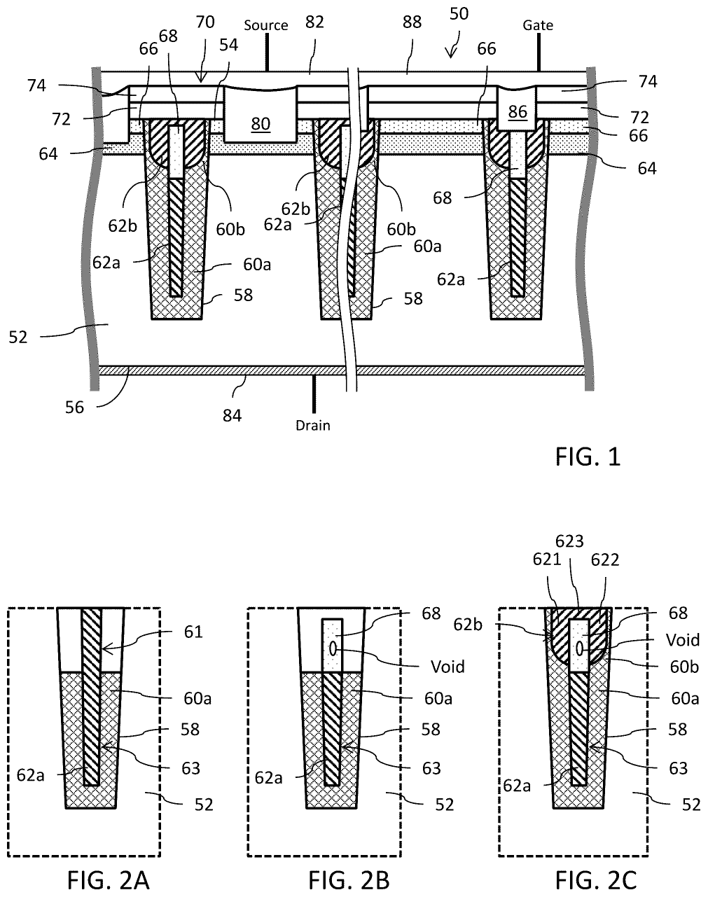

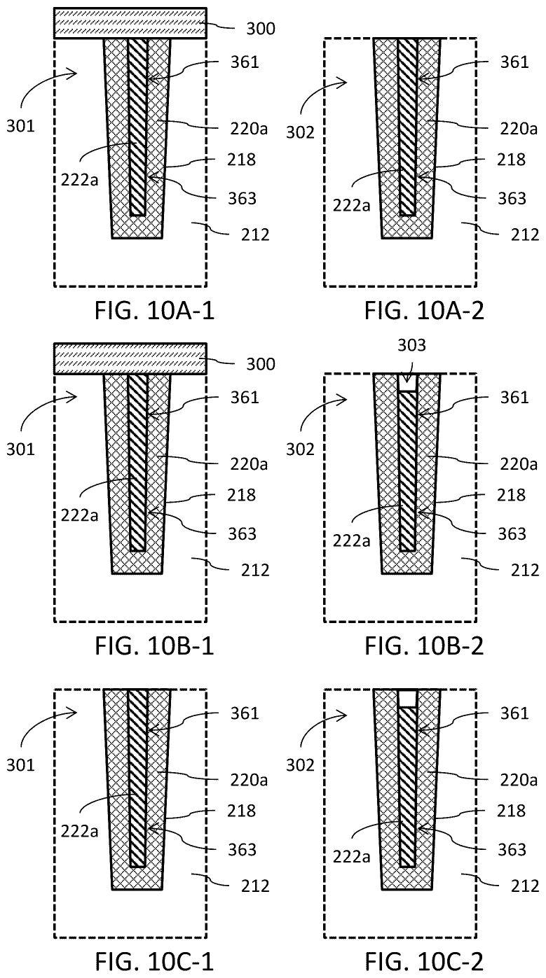

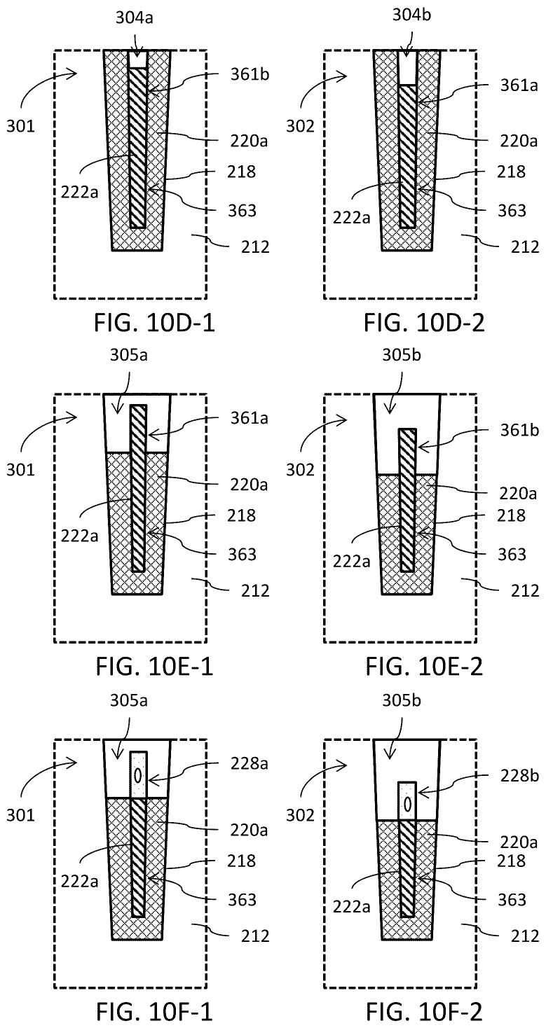

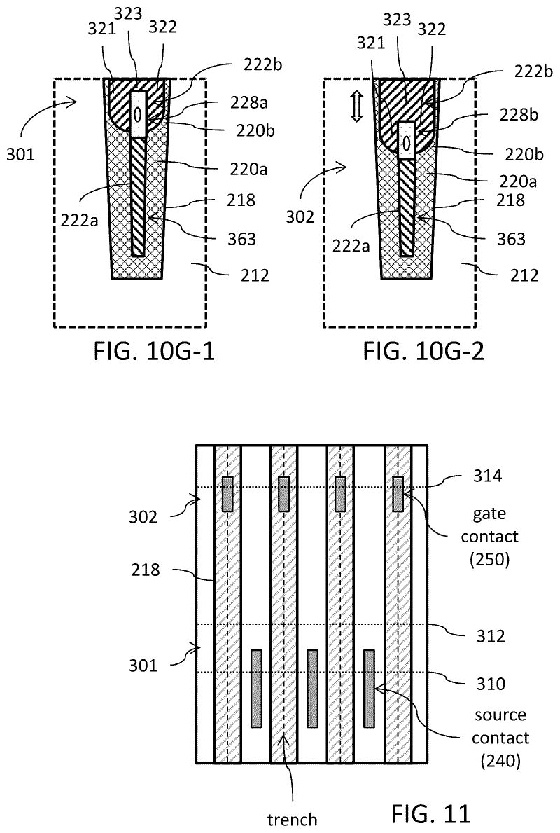

The side walls and bottom of each trench 218 are lined with a first insulating layer 220a. For example, the insulating layer 220a may comprise a thick oxide layer. The trench 218 is then filled by a first polysilicon material 222a, with the insulating layer 220a insulating the first polysilicon material 222a from the substrate 212. The first polysilicon material 222a is a heavily n-type doped polysilicon material (for example, Phosphorus doped with a doping concentration of 5×10²⁰ at/cm³). During the process for fabricating the transistor 210, regions 301 of the upper surface of the substrate 212 are covered by a mask 300 (FIG. 10A-1). However, the mask includes an opening at regions 302 where transistor gate contacts are going to be formed (FIG. 10A-2). A first selective recess of the upper portion 361 of the first polysilicon material 222a at regions 302 is then performed to produce opening 303 (see, FIGS. 10B-1 and 10B-2) by selectively removing a first portion of the first polysilicon material 222a at regions 302. This recess operation may, for example, be implemented using a dry polysilicon selective etch. The mask 300 is then removed (see, FIGS. 10C-1 and 10C-2). A second selective recess of the upper portion 361 of the first polysilicon material 222a at regions 301 and 302 is then performed to produce openings 304a and 304b (see, FIGS. 10D-1 and 10D-2), where opening 304b is an extension in depth of opening 303, by selectively removing a second portion of the first polysilicon material 222a at regions 301 and further selectively removing a third portion of the first polysilicon material 222a at regions 302. This recess operation may, for example, be implemented using a dry polysilicon selective etch. As a result of the selective recessing operations, the first polysilicon material 222a at regions 301 is recessed to a first level and the first polysilicon material 222a at regions 302 is recessed to a second level (greater in depth than the first level). An upper portion of the insulating layer 220a (which would be adjacent to both the doped body region 124 and doped region 126) is removed from the trench 218 to expose a corresponding upper portion 361a of the first polysilicon material 222a in region 301 and a corresponding upper portion 361b of the first polysilicon material 222a in region 302 (see, FIGS. 10E-1 and 10E-2). The removal of the upper portion of the insulating layer 220a may, for example, be accomplished using a wet buffered oxide etch (BOE) that is selective to remove the oxide material of the insulating layer 220a while leaving the first polysilicon material 222a and substrate 212 in place. It will be noted that because of the difference in depths of the openings 304a, 304b that result from the recess of the first polysilicon material 222a in regions 301 and 302, respectively, there will be a corresponding difference in depths of the openings 305a and 305b, respectively, in the regions 301 and 302 produced by the wet BOE (where opening 305a has a first depth and opening 305b has a second depth that is greater than the first depth). The exposed upper portions 361a, 361b of the first polysilicon material 222a are then converted (for example, using a thermal oxidation process) to form polyoxide regions 228a, 228b that are vertically aligned in the trench 218 with the remaining (lower) portions of the first polysilicon material 222a (see, FIGS. 10F-1 and 10F-2). For reasons previously noted herein, this thermal oxidation process can in some cases produce voids in polyoxide regions 228a, 228b. It will be noted that the upper surfaces of the polyoxide regions 228a, 228b are recessed to different levels in the first and second regions 301, 302, respectively. The remaining lower portions of the first polysilicon material 222a form field plate electrodes of the transistor 210 (referred to also as the polysource regions because they are typically electrically shorted to the source regions 226—this electrical connection is not explicitly shown in the figures). The side walls and bottom of the upper portion of each trench 218 are then lined with a second insulating layer 220b. For example, the insulating layer 220b may comprise a thermally grown oxide layer. The upper portion of each trench 218 is then filled by a second polysilicon material 222b, with the insulating layer 220b insulating the second polysilicon material 222b from the substrate 212 (including regions 224 and 226). See, FIGS. 10G-1 and 10G-2. The second polysilicon material 222b forms the gate (referred to as a polygate region) of the transistor 210 and includes a first (for example, left) gate lobe 321 and second (for example, right) gate lobe 322 which longitudinally extend in the trench on opposite sides of the polyoxide regions 228a, 228b. The first and second gate lobes are connected by a gate bridge portion 323 laterally extending over the polyoxide regions 228a, 228b. It will be noted that the vertical thicknesses of the bridge portions 323 are different in the regions 301 and 302. Specifically, the bridge portion 323 in region 302 where the transistor gate contact is going to be formed is thicker than the bridge portion 323 in region 301. The reason for, and advantage of, this will be apparent from the discussion below concerning the subsequent provision of the gate contact. It will also be noted that the first and second gate lobes 321, 322, extend to different depths in depths in the first and second regions 301, 302, respectively (the depth being greater in region 302 than in region 301). The insulating layer 220b forms the gate oxide layer.

A stack 230 of layers is formed above the upper surface of the substrate. The stack 230 includes an undoped oxide (for example, tetraethyl orthosilicate (TEOS)) layer 232 and a glass (for example, borophosphosilicate glass (BPSG)) layer 234. The stack 230 may further include additional insulating and/or barrier layers if needed. For example, a thin silicon nitride layer (not explicitly shown) may be provided between TEOS layer 232 and the upper surface 214 of the substrate 212.

With reference to the left side of FIG. 9, a source metal contact 240 extends through the layers of the stack 230, positioned between the locations of adjacent trenches 218, to make electrical contact with the doped source region 226. Each source metal contact 240 extends depthwise into the substrate to pass through the doped source region 236 and partially into the doped body region 234 (thus providing a body contact for the transistor 210 that is tied to the source). A source metal layer 242 extends over both the stack 230 and the source metal contacts 240 to provide an electrical connection to and between all source metal contacts 240. The layers of the stack 230 insulate both the source metal layer 242 and the source metal contacts 240 from the polygate (second polysilicon region 222b).

With reference now to the right side of FIG. 9, the gate metal contact 250 for each polygate extends through the layers of the stack 230, positioned in vertical alignment with the location of the trench 218 to make electrical contact with the bridge portion 323 in the region 302. Each gate metal contact 250 extends depthwise only partially into an upper part of the (thicker) bridge portion 323 at regions 302. A gate metal layer 248 extends over both the stack 230 and the gate metal contacts 250 to provide an electrical connection to and between all gate metal contacts 250. The layers of the stack 230 insulate both the gate metal layer 248 and the gate metal contacts 250 from the source metal contacts and source regions.

The process for formation of the gate contact 250 utilizes a mask with a mask opening aligned with the center of the trench 218 in region 302. An etch performed using this mask produces a gate opening extending through the stack 230 and partially into the bridge 323 of the second polysilicon region 222b which forms the polygate. That etch may include multiple, discrete, etch steps including a first etch to remove the layers of the stack 230 and a second etch to extend into the bridge 323 for a desired depth (taking advantage of the extra thickness available in region 302 for the bridge 323). The size of the mask opening, and the corresponding gate opening, is typically designed to be about, and more preferably less than, one-half the size (width) of the trench 218 and is generally speaking preferably aligned with the center of the trench. A barrier layer 292 formed of a Titanium-Titanium Nitride (Ti—TiN) material is then conformally deposited into the etched gate opening, and the gate opening is then filled with a plug 294 made of a conductive material (such as, for example, Tungsten) to form the gate contact 250. It will be noted that the gate opening for insertion of the gate contact 250 has a depth extending partially into the gate bridge 323 without reaching the polyoxide region 228 or the included void. The double ended arrow in FIG. 10G-2 illustrates the safety offset distance that accrues in region 302 due to the extended depths of the recessed first polysilicon material 222a in regions 302 as compared to region 301. See, process steps shown in FIGS. 10B-2, 10C-2, 10D-2 and 10E-2.

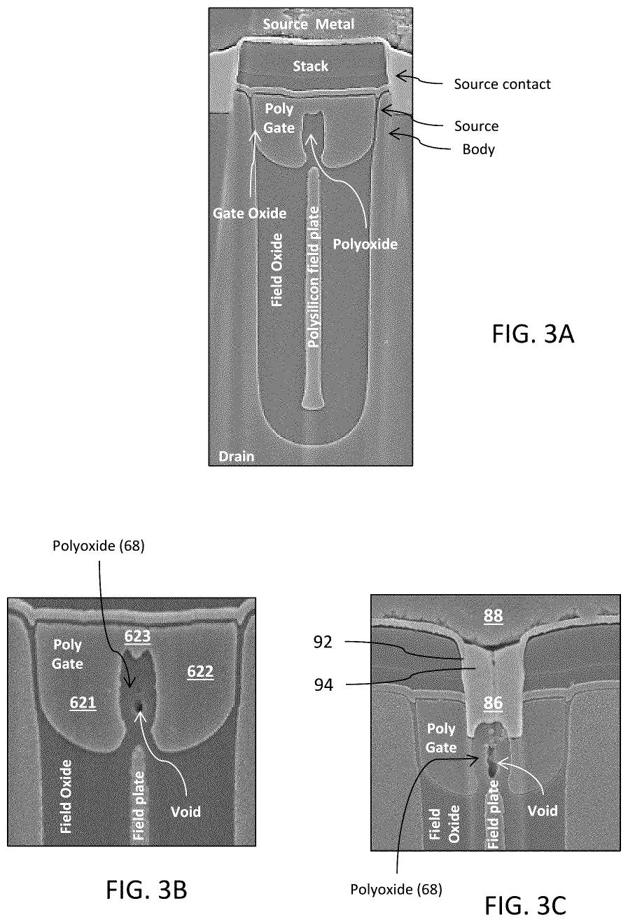

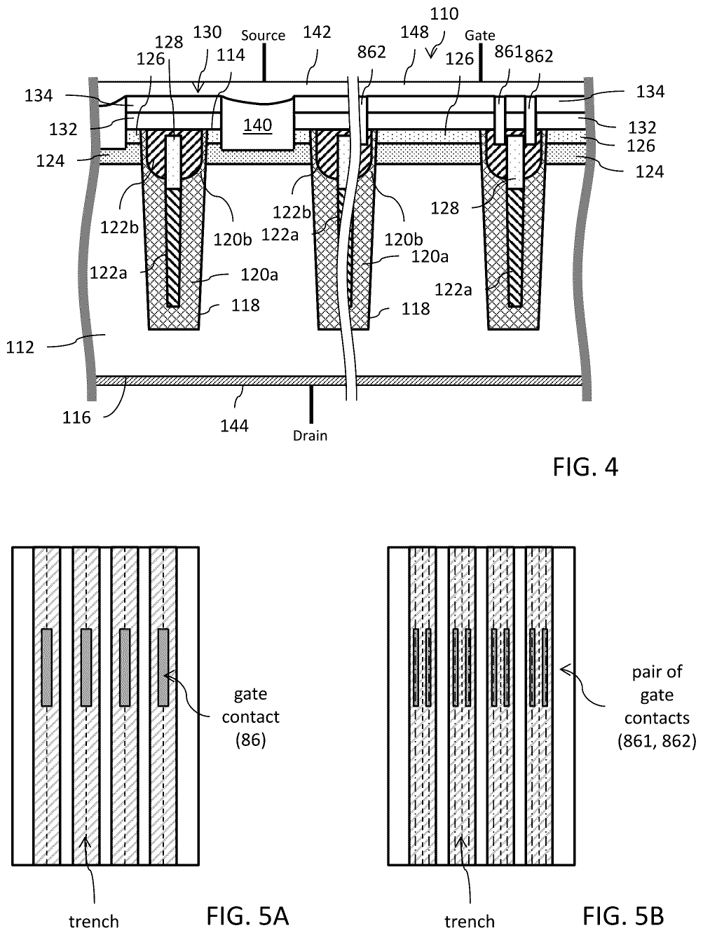

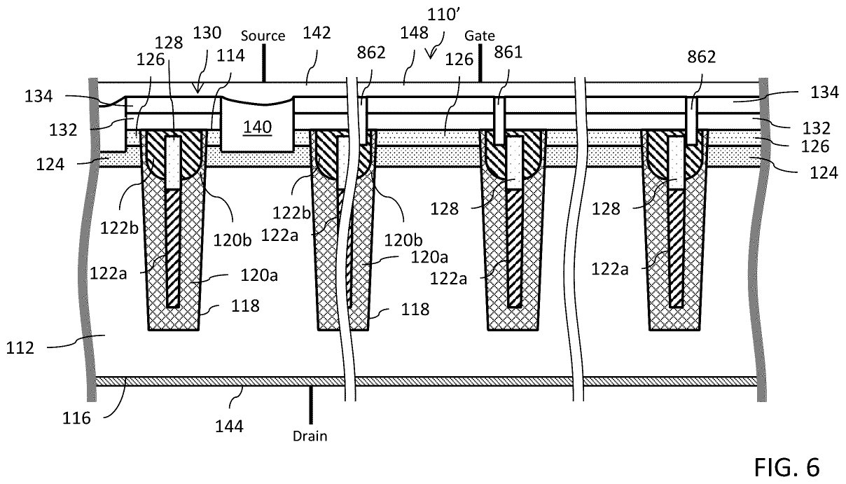

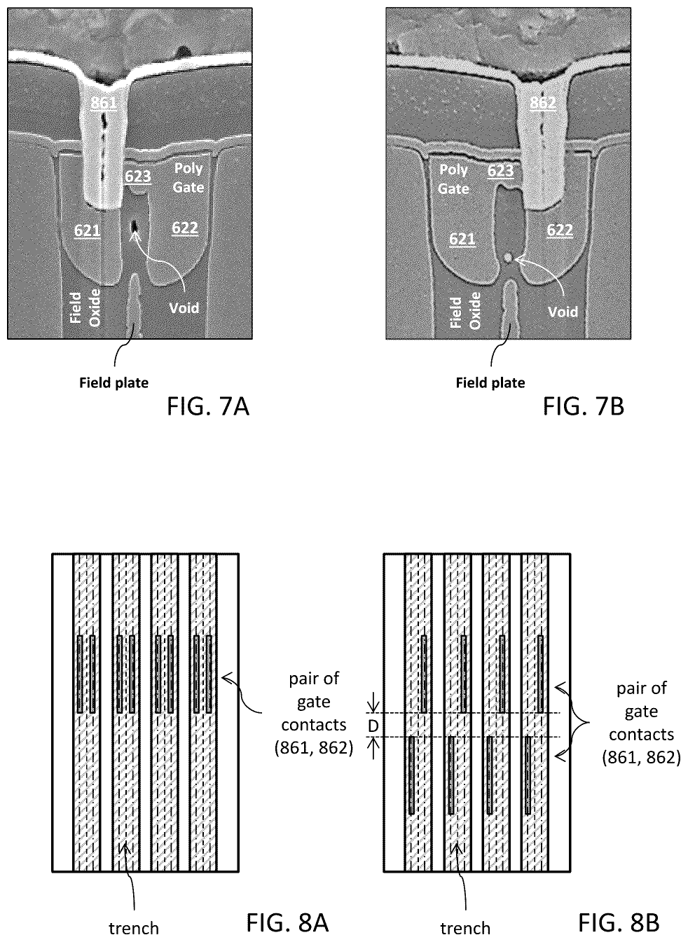

It will be noted that because of the increased thickness of the bridge portion 323 in the region 302, there is a significantly reduced risk that etch of the contact opening to a depth extending partially into the bridge portion 323 will reach the polyoxide region 228b. Additionally, this etched opening will have a more uniform topology (compare to the non-uniform shape of the contact opening as shown by FIG. 3C). As a result, the conformally deposited Ti—TiN barrier layer will completely cover this location and provide the necessary insulation presence and thickness. Furthermore, there is a corresponding reduced risk of the conductive material for the contact 250 that is deposited in the gate opening presenting a leakage path or short-circuit between the polygate and the polysource provided by the field plate. Additionally, because the contact 250 can be aligned with the center of the trench, as opposed to being offset from the center of the trench as in FIGS. 4 and 6, this architecture supports provision of a device with a reduced pitch.

The cross-sections on the left and right sides of FIG. 9 are, in practice, actually longitudinally offset from each other in the direction perpendicular to the cross-section (i.e., into and out of the page of the illustration). In this configuration, an insulating separation is provided between the source metal layer 242 and the gate metal layer 248.

A drain metal layer 244 extends over the back side 216 of the substrate 212 to provide a metal connection to the drain.

The transistor 210 could instead be a pMOS type transistor where the substrate 212 and doped source region 226 are both p-type doped and the body region 224 is n-type doped.

FIG. 11 is a plan view (i.e., looking downward towards the front surface of the substrate) illustrating the layout for the transistor 210 with a specific focus showing the relative locations of the contacts 240 and 250. The dashed line indicates the center line of each longitudinally extending trench. The dotted line 310 indicates the general location of the cross-section for the left side of FIG. 9. The dotted line 312 indicated the general location of the cross-section shown for all of the FIGS. 10A-10G with a “-1” suffix which are related to region 301. The dotted line 314 indicates the general location of the cross-section for the right side of FIG. 9 as well as the general location of the cross-section shown for all of the FIGS. 10A-10G with a “-2” suffix which are related to region 302.

For the discussion herein, it will be noted that the term “longitudinal” refers to a first direction for example extending along the length of the trench and the term “lateral” refers to a second direction for example extending along the width of the trench. The longitudinal and lateral directions are perpendicular to each other and extend parallel to an upper surface of the semiconductor substrate.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

1. A method, comprising:
forming a trench in a semiconductor substrate;
lining sidewalls and a bottom of the trench with a first insulating layer;
filling the trench with a first polysilicon material;
forming a mask covering the trench at a first region of the semiconductor substrate, said mask including a first opening over the trench at a second region of the semiconductor substrate;
using said first opening, etching to selectively remove a first portion of the first polysilicon material at said second region of the semiconductor substrate;
removing the mask;
etching to selectively remove a second portion of the first polysilicon material at said first region of the semiconductor substrate and selectively remove a third portion of the first polysilicon material at said second region of the semiconductor substrate;
etching to selectively remove an upper portion of the first insulating layer in said trench to a first depth at said first region of the semiconductor substrate and to second depth at said second region of the semiconductor substrate, said second depth being greater than said first depth, to expose an upper portion of the first polysilicon material in an upper portion of said trench;
converting the exposed upper portion of the first polysilicon material in said trench to a polyoxide material;
lining sidewalls and a bottom of the upper portion of said trench with a second insulating layer; and
filling the upper portion of said trench with a second polysilicon material.

2. The method of claim 1, wherein a remaining portion of the first polysilicon material in said trench forms a transistor field plate electrode, and wherein the second polysilicon material forms a transistor gate electrode.

3. The method of claim 2, wherein the semiconductor substrate is doped with a first conductivity type, further comprising:
implanting a first doped region that is doped with the first conductivity type at the upper surface of the semiconductor substrate;
burying a second doped region that is doped with a second conductivity type, that is opposite the first conductivity type, below the first doped region; and
wherein said trench extends in depth completely through both of the first and second doped regions.

4. The method of claim 3, wherein the semiconductor substrate forms a transistor drain, the first doped region forms a transistor source and the second doped region forms a transistor body.

5. The method of claim 4, further comprising:
forming a stack of insulating layers covering the transistor gate electrode, the trench and the semiconductor substrate;
at said first region, forming a second opening extending through the stack of insulating layers, through the first doped region and partially extending into the second doped region; and
forming a source contact in said second opening.

6. The method of claim 2, wherein the second polysilicon material that forms the transistor gate electrode includes a first gate lobe on one side of the polyoxide material, a second gate lobe on an opposite side of the polyoxide material, and a gate bridge extending over the polyoxide material.

7. The method of claim 6, further comprising:
forming a stack of insulating layers covering the transistor gate electrode, the trench and the semiconductor substrate;
at said second region, forming a third opening aligned with the trench and extending through the stack of insulating layer and partially extending into the gate bridge; and
forming a gate contact in said third opening.

8. A method, comprising:
forming a trench in a semiconductor substrate;
lining sidewalls and a bottom of the trench with a first insulating layer;
filling the trench with a first polysilicon material;
selectively recessing the first polysilicon material in the trench at a first region of the semiconductor substrate to a first level;
selectively recessing the first polysilicon material in the trench at a second region of the semiconductor substrate to a second level, said second level being greater in depth than said first level;
selectively recessing an upper portion of the first insulating layer in said trench to a first depth in the first region and to a second depth in the second region in order to expose an upper portion of the recessed first polysilicon material in an upper portion of said trench;
converting the exposed upper portion of the first polysilicon material in said trench to a polyoxide material;
lining sidewalls and a bottom of the upper portion of said trench with a second insulating layer; and
filling the upper portion of said trench with a second polysilicon material.

9. The method of claim 8, wherein a remaining portion of the first polysilicon material in said trench forms a transistor field plate electrode, and wherein the second polysilicon material forms a transistor gate electrode.

10. The method of claim 9, wherein the second polysilicon material that forms the transistor gate electrode includes a first gate lobe on one side of the polyoxide material, a second gate lobe on an opposite side of the polyoxide material, and a gate bridge extending over the polyoxide material.

11. The method of claim 10, further comprising:
forming a stack of insulating layers covering the transistor gate electrode, the trench and the semiconductor substrate;
at said second region, forming an opening aligned with the trench and extending through the stack of insulating layer and partially extending into the gate bridge; and
forming a gate contact in said opening.

12. An integrated circuit transistor device, comprising:
a semiconductor substrate providing a drain;
a first doped region in the semiconductor substrate providing a source;
a second doped region buried in the semiconductor substrate below the first doped region and providing a body;
a trench extending into the semiconductor substrate and passing through the first and second doped regions;
a polyoxide region within the trench; and
a polygate region within the trench, said polygate region comprising: a first gate lobe on a first side of the polyoxide region, a second gate lobe on a second side of the polyoxide region opposite said first side, and a gate bridge extending over the polyoxide region;
wherein, at a first region of the semiconductor substrate, the polyoxide region is recessed within the trench to a first level and the first and second gate lobes extend to a first depth within the trench;
wherein, at a second region of the semiconductor substrate, the polyoxide region is recessed within the trench to a second level and the first and second gate lobes extend to a second depth within the trench; and
wherein said second level is greater in depth than said first level the first and said second depth is greater than said first depth.

13. The integrated circuit transistor device of claim 12, wherein the gate bridge has a first thickness in the first region and a second thickness in the second region, said second thickness being greater than the first thickness.

14. The integrated circuit transistor device of claim 12, further comprising a polysource region within said trench, wherein the polysource region is longitudinally aligned with the polyoxide region.

15. The integrated circuit transistor device of claim 14, wherein said polyoxide region is an oxidized portion of said polysource region.

16. The integrated circuit transistor device of claim 12, further comprising:
a stack of insulating layers covering the transistor gate electrode, the trench and the semiconductor substrate;
an opening at the second region aligned with the trench and extending through the stack of insulating layer and partially extending into the gate bridge; and
a gate contact in said opening.

17. The integrated circuit transistor device of claim 12, further comprising:
a stack of insulating layers covering the transistor gate electrode, the trench and the semiconductor substrate;
an opening at said first region extending through the stack of insulating layers, through the first doped region and partially extending into the second doped region; and
a source contact in said opening.

18. An integrated circuit transistor device, comprising:
a semiconductor substrate providing a drain;
a first doped region in the semiconductor substrate providing a source;
a second doped region buried in the semiconductor substrate below the first doped region and providing a body;
a trench extending into the semiconductor substrate and passing through the first and second doped regions;
a polyoxide region within the trench;
a polygate region within the trench, said polygate region comprising: a first gate lobe on a first side of the polyoxide region, a second gate lobe on a second side of the polyoxide region opposite said first side, and a gate bridge extending over the polyoxide region;
wherein, at a first region of the semiconductor substrate, the gate bridge has a first thickness;
wherein, at a second region of the semiconductor substrate, the gate bridge has a second thickness that is greater than the first thickness;
a stack of insulating layers covering the transistor gate electrode, the trench and the semiconductor substrate;
an opening at said second region of the semiconductor substrate aligned with the trench and extending through the stack of insulating layer and partially extending into the second thickness of the gate bridge; and
a gate contact in said opening.

19. The integrated circuit transistor device of claim 18, further comprising a polysource region within said trench, wherein the polysource region is longitudinally aligned with the polyoxide region.

20. The integrated circuit transistor device of claim 19, wherein said polyoxide region is an oxidized portion of said polysource region.
